(19) United States
(12) Patent Application Publication
(10) Pub. No.: US 2025/0169088 A1
(43) Pub. Date: May 22, 2025

(54) SEMICONDUCTOR DEVICE

(71) Applicant: Mitsubishi Electric Corporation, Tokyo (JP)

(72) Inventors: Taro MORIYA, Tokyo (JP); Yuji EBIIKE, Tokyo (JP)

(73) Assignee: Mitsubishi Electric Corporation, Tokyo (JP)

(21) Appl. No.: 18/822,040

(22) Filed: Aug. 30, 2024

(30) Foreign Application Priority Data
Nov. 20, 2023 (JP) 2023-196912

(51) Int. Cl. H01L 29/739; H01L 29/06

(52) U.S. Cl. CPC H10D 12/481; H10D 62/127

(57) ABSTRACT

A semiconductor device includes a semiconductor substrate, a gate insulating film formed on an inner wall of a groove that reaches a drift layer from a surface of the semiconductor substrate, a gate trench and a raised electrode that are formed inside the groove on the gate insulating film, an interlayer insulating film, and an emitter electrode. The raised electrode includes a first raised electrode and a second raised electrode, the first raised electrode being connected to the emitter electrode via a contact via that penetrates the interlayer insulating film, the second raised electrode being positioned between the first raised electrode and the gate trench in a direction in which the groove extends in plan view. The second raised electrode includes a narrow width portion having a width narrower than a width of the first raised electrode in plan view.

### BACKGROUND OF THE INVENTION

### Field

The present disclosure relates to a semiconductor device.

### Background

JP 2021-15885 A discloses a semiconductor device having a trench gate structure with a two-layer structure. In the semiconductor device, a lower electrode, which is a shield electrode, is extended beyond an upper electrode, which is a gate electrode, on both end portions of a gate trench in the longitudinal direction of the gate trench, and then raised to the surface of an n⁻-type drift layer. In JP 2021-15885 A, at a boundary portion between the lower electrode raised to the n⁻-type drift layer and the upper electrode, the gate trench is made wider. This makes it possible to make the thickness of an intermediate insulating film existing at the boundary portion sufficiently thick not only on the entry side of the gate trench but also on the bottom portion side. By this means, it is possible to secure a dielectric withstand voltage of the intermediate insulating film that insulates the lower electrode from the upper electrode.

The lower electrode raised to the surface of the n⁻-type drift layer is brought into contact with a contact via to be a raised electrode at an emitter potential. To secure a bonding margin between the lower electrode and the contact via, the width of the raised electrode is preferably wide.

However, with the method described above, the width of the raised electrode is narrow.

The bonding margin described above can be secured by simply increasing the width of the raised electrode. However, in this case, embeddability of a material becomes a problem when the lower electrode is deposited for the raised electrode. This is a problem to be caused by the deposition state becoming worse as the width of a groove in which the material is embedded is wider. There is a concern that the upper electrode that could be properly removed by etching may be unintentionally left within the raised electrode as a result of the deposition state of the lower electrode becoming worse by the width of the raised electrode being increased. The upper electrode left within the raised electrode is to be charged at the emitter potential, and in a case where the upper electrode left within the raised electrode makes contact with the upper electrode within the gate trench in that state, the upper electrode and the lower electrode are short-circuited.

### SUMMARY

To solve the above-described problem, an object of the present disclosure is to provide a semiconductor device capable of preventing a short-circuit between an upper electrode and a lower electrode while securing a bonding margin between the lower electrode and a contact via.

The features and advantages of the present disclosure may be summarized as follows.

According to an aspect of the present disclosure, a semiconductor device comprises a semiconductor substrate including a drift layer of a first conductivity type, a base layer of a second conductivity type formed on the drift layer, and an emitter region of the first conductivity type formed in an upper layer portion of the base layer; a gate insulating film formed on an inner wall of a groove that penetrates the emitter region and the base layer from a surface of the semiconductor substrate to reach the drift layer; a gate trench and a raised electrode that are formed inside the groove on the gate insulating film; an interlayer insulating film formed on the gate trench and the raised electrode; and an emitter electrode formed on the semiconductor substrate and the interlayer insulating film and connected to the emitter region and the base layer, wherein the gate trench includes a lower electrode formed inside the groove and an upper electrode formed inside the groove above the lower electrode via an intermediate insulating film, the raised electrode connects the lower electrode to the emitter electrode and is insulated from the upper electrode by the intermediate insulating film, the raised electrode includes a first raised electrode and a second raised electrode, the first raised electrode being connected to the emitter electrode via a contact via that penetrates the interlayer insulating film, the second raised electrode being positioned between the first raised electrode and the gate trench in a direction in which the groove extends in plan view, and the second raised electrode includes a narrow width portion having a width narrower than a width of the first raised electrode in plan view.

Other and further objects, features and advantages of the invention will appear more fully from the following description.

### BRIEF DESCRIPTION OF DRAWINGS

FIG. 1 is a plan view of a semiconductor device according to a first embodiment of the present disclosure.

FIG. 2 is an enlarged view of FIG. 1.

FIG. 3 is a cross-sectional view of the gate trench according to the first embodiment of the present disclosure and is a cross-sectional view along a-a in FIG. 2.

FIG. 4 is a cross-sectional view along b-b in FIG. 2 and is a cross-sectional view in the longitudinal direction of the raised electrode.

FIG. 5 is a cross-sectional view along c-c in FIG. 2 and is a cross-sectional view in the short-side direction of the first raised electrode.

FIG. 6 is a plan view of the semiconductor device according to a modification of the first embodiment of the present disclosure.

FIG. 7 is a plan view of the semiconductor device according to a modification of the first embodiment of the present disclosure.

FIG. 8 is a plan view of the semiconductor device according to a modification of the first embodiment of the present disclosure.

FIG. 9 is a plan view of the semiconductor device according to a second embodiment of the present disclosure.

FIG. 10 is a cross-sectional view along d-d in FIG. 9.

FIG. 11 is a plan view of the semiconductor device according to a modification of the second embodiment of the present disclosure.

FIG. 12 is a plan view of the semiconductor device according to a modification of the second embodiment of the present disclosure.

FIG. 13 is a plan view of the semiconductor device according to a third embodiment of the present disclosure.

FIG. 14 is a plan view of the semiconductor device according to a modification of the third embodiment of the present disclosure.

FIG. 15 is a plan view of the semiconductor device according to a fourth embodiment of the present disclosure.

FIG. 16 is a plan view of the semiconductor device according to a modification of the fourth embodiment of the present disclosure.

FIG. 17 is a plan view of the semiconductor device according to a fifth embodiment of the present disclosure.

FIG. 18 is an enlarged view of FIG. 17.

FIG. 19 is a plan view of the semiconductor device according to a modification of the fifth embodiment of the present disclosure.

FIG. 20 is a view illustrating the lower electrode deposited for the first raised electrode according to a comparative example of the present disclosure.

FIG. 21 is a view illustrating the upper electrode left on the first raised electrode according to a comparative example of the present disclosure.

### DESCRIPTION OF EMBODIMENTS

A semiconductor device according to the embodiments of the present disclosure will be described with reference to the drawings. The same components will be denoted by the same symbols, and the repeated description thereof may be omitted.

### First Embodiment

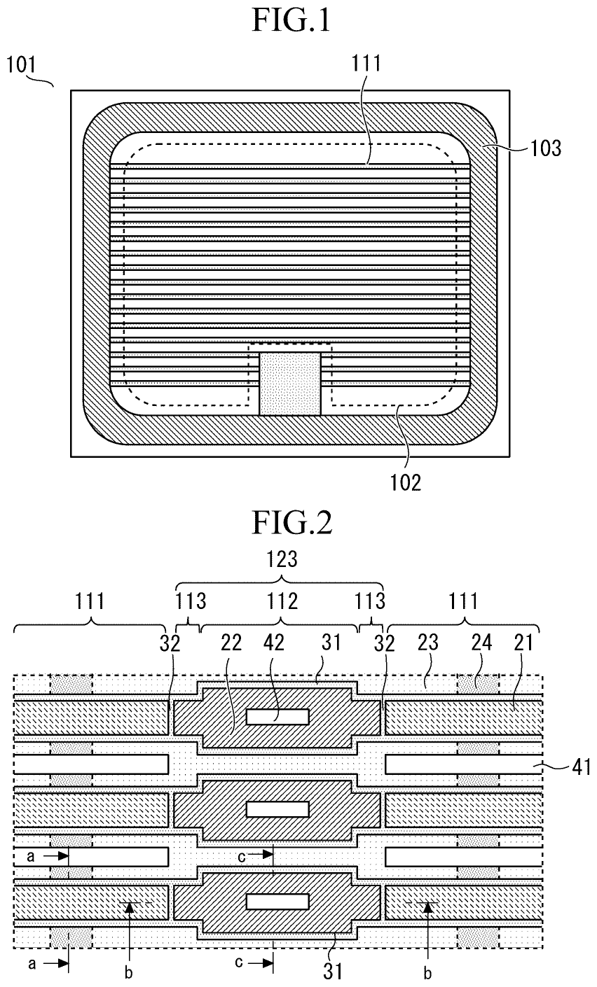

FIG. 1 is a plan view of a semiconductor device 101 according to a first embodiment of the present disclosure. The semiconductor device 101 includes a gate trench 111 formed so as to extend in one direction and a raised electrode 123 that is connected to the gate trench 111 and that is not illustrated. The semiconductor device 101 is, for example, an insulated gate bipolar transistor (IGBT) having a trench gate structure.

In FIG. 1, the semiconductor device 101 includes a plurality of gate trenches 111, and the plurality of gate trenches 111 are arranged at regular intervals in a direction perpendicular to the extending direction thereof. However, the gate trenches 111 does not necessarily have to be plural, and it is only necessary that one or more gate trench 111 is provided.

An active region 102 is a region that includes the gate trench 111 and the raised electrode 123 and in which the semiconductor device 101 functions as the IGBT.

FIG. 2 is an enlarged view of FIG. 1. The raised electrode 123 includes a first raised electrode 112 and a second raised electrode 113 positioned between the first raised electrode 112 and the gate trench 111. The width of the second raised electrode 113 is equal to the width of the gate trench 111. On the other hand, the width of the first raised electrode 112 is wider than the widths of the second raised electrode 113 and the gate trench 111. Note that the width of the gate trench 111 or the raised electrode 123 is its width in plan view of the semiconductor device 101.

An upper electrode 21, a lower electrode 22, and an intermediate insulating film 32 that insulates the upper electrode 21 from the lower electrode 22 are formed on the gate trench 111, which will be described later. FIG. 2 illustrates a plane on which the upper electrode 21 exists.

By the raised electrode 123, the lower electrode 22 is raised to the surface of a semiconductor substrate 10 and exposed. The lower electrode 22 being raised is enclosed by an insulating film 31 and the intermediate insulating film 32. The lower electrode 22 is insulated from the upper electrode 21 by the intermediate insulating film 32.

The lower electrode 22 raised to the surface of the semiconductor substrate 10 is connected to a contact via 42 at the first raised electrode 112. The contact via 42 is provided to electrically connect the lower electrode 22 to an emitter electrode 51 not illustrated to set the lower electrode 22 at an emitter potential.

By connecting the lower electrode 22 to the contact via 42 at the first raised electrode 112 having an increased width as in the present disclosure, a bonding margin between the lower electrode 22 and the contact via 42 can be secured. This can facilitate bonding.

Further, the area of the contact via 42 can be increased by an amount corresponding to an increase in the width of the lower electrode 22, so that the contact resistance can be lowered.

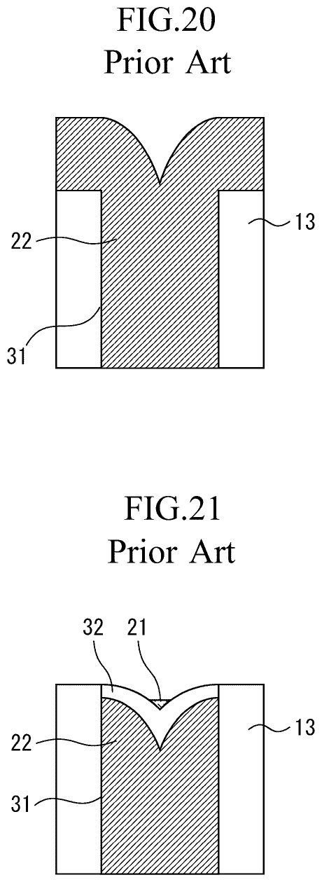

Here, even in a case where all the raised electrodes 123 are the first raised electrodes 112, the bonding margin described above can be secured. However, in this case, an embedding defect of a material becomes a problem when the lower electrode 22 is deposited for the first raised electrode 112. While this has been already described as background, this will be described in detail below using FIGS. 20 and 21.

FIG. 20 is a view illustrating the lower electrode 22 deposited for the first raised electrode 112 according to a comparative example of the present disclosure. Here, a cross-section in the short-side direction of the first raised electrode 112 is illustrated, and only an upper layer portion of the semiconductor substrate 10 is illustrated. It is known that the deposition state of the lower electrode 22 becomes worse in a case where a material is embedded in the first raised electrode 112 having a wider width than in a case where the material is embedded in the second raised electrode 113 having a narrower width. In other words, it is difficult to embed the material at the center of the first raised electrode 112, and thus, the deposited lower electrode 22 does not become flat but has a V shape as illustrated in FIG. 20.

The deposited lower electrode 22 is etched, and the portion exposed on the semiconductor substrate 10 is removed. While the intermediate insulating film 32 and the upper electrode 21 are further laminated, the upper electrode 21 to be laminated here should be left only within the gate trench 111, and the upper electrode 21 within the first raised electrode 112 should be removed by etching. However, as a result of the V shape of the lower electrode 22 being reflected, the upper electrode 21 that should not be left is left at the first raised electrode 112.

FIG. 21 is a view illustrating the upper electrode 21 left on the first raised electrode 112 according to a comparative example of the present disclosure. Also here, a cross-section in the short-side direction of the first raised electrode 112 is illustrated, and only the upper layer portion of the semiconductor substrate 10 is illustrated. As illustrated in FIG. 21, the upper electrode 21 that cannot be removed by etching is left at a central position of the first raised electrode 112.

This upper electrode 21 that cannot be entirely removed exists on an upper layer of the semiconductor substrate 10 and thus can make contact with the contact via 42 at the emitter potential. Here, the first raised electrode 112 is adjacent to the gate trench 111 in a state where the upper electrode 21 that cannot be entirely removed is left in the upper layer portion. In other words, the upper electrode 21 left within the first raised electrode 112 is likely to make contact with the upper electrode 21 in the gate trench 111. If the upper electrode 21 left within the first raised electrode 112 makes contact with the upper electrode 21 in the gate trench 111, the upper electrode 21 and the lower electrode 22 are short-circuited.

On the other hand, in the raised electrode 123 of the present disclosure, by positioning the second raised electrode 113 between the first raised electrode 112 and the gate trench 111, an embedding defect of the lower electrode 22 can be avoided at both ends of the raised electrode 123. As a result, a short-circuit of the upper electrode 21 and the lower electrode 22 can be prevented.

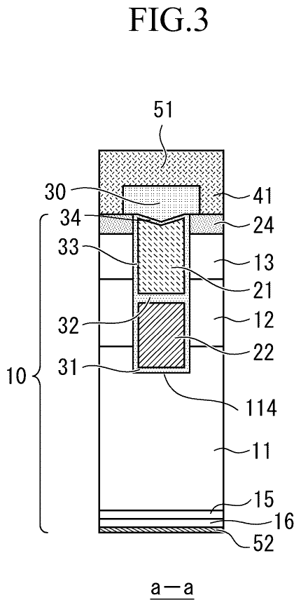

FIG. 3 is a cross-sectional view of the gate trench 111 according to the first embodiment of the present disclosure and is a cross-sectional view along a-a in FIG. 2. The gate trench 111 is embedded within a groove 114 formed on the surface of the semiconductor substrate 10. On the semiconductor substrate 10, a collector electrode 52 is positioned on the bottom surface, a p-type collector layer 16, an n-type buffer layer 15, an n-type drift layer 11, an n-type carrier accumulation layer 12, a p-type base layer 13, and an n+-type emitter region 24 are sequentially laminated on the collector electrode 52. Note that n+ indicates that impurity concentration is higher relative to n-type. Here, FIG. 3 illustrates a cross-sectional view of the gate trench 111 at a portion where the next upper layer of the p-type base layer 13 is the n+-type emitter region 24. However, it should be noted that the gate trench 111 is also embedded at a portion where the next upper layer of the p-type base layer 13 is a p⁺-type layer region 23. Note that p⁺ indicates that impurity concentration is higher relative to p-type.

The insulating films 31 and 33 are formed on the inner wall of the groove 114 having a depth that penetrates from the n⁺-type emitter region 24, which is the upper layer of the semiconductor substrate 10, to the n-type carrier accumulation layer 12 and reaches the n-type drift layer 11. The insulating film 31 insulates the lower electrode 22 from the semiconductor substrate 10. The insulating film 33 insulates the upper electrode 21 from the semiconductor substrate 10. Hereinafter, the insulating films 31 and 33 will be collectively referred to as a gate insulating film.

The gate trench 111 is formed on the gate insulating film inside the groove 114. The gate trench 111 includes the lower electrode 22 formed inside the groove 114 and the upper electrode 21 formed inside the groove 114 above the lower electrode 22 via the intermediate insulating film 32. The upper electrode 21 performs switching operation as the IGBT. The lower electrode 22 is formed to reduce feedback capacity by being fixed at the emitter potential and to achieve improvement in electrical characteristics as the IGBT. The lower electrode 22 is constituted of, for example, a doped Poly-Si.

The intermediate insulating film 32 is formed between the lower electrode 22 and the upper electrode 21 and insulates the lower electrode 22 from the upper electrode 21.

An interlayer insulating film 30 is formed in an upper portion of the gate trench 111 via the insulating film 34. The interlayer insulating film 30 is covered by the emitter electrode 51. The emitter electrode 51 is connected to the n⁺-type emitter region 24 and the p⁺-type layer region 23 that are upper layers of the semiconductor substrate 10 via the contact via 41. This makes it possible to set the n⁺-type emitter region 24 and the p⁺-type layer region 23 at the emitter potential.

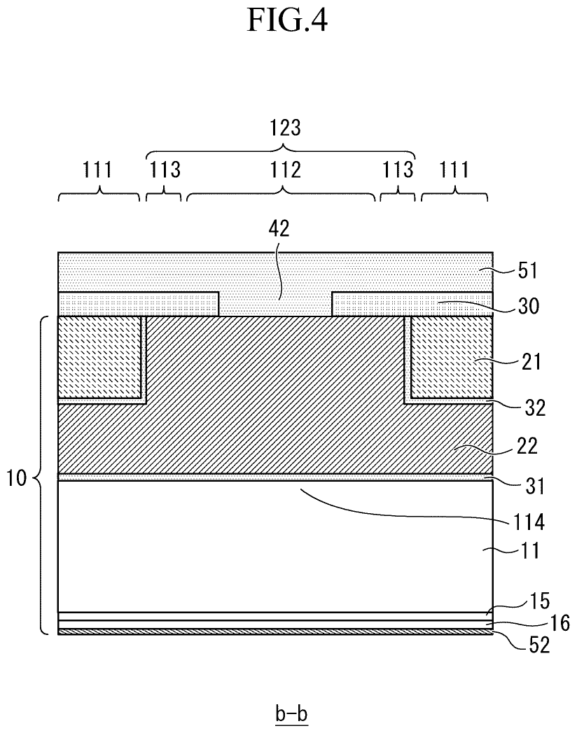

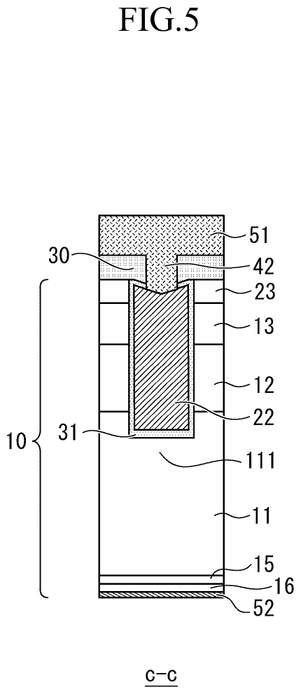

FIG. 4 is a cross-sectional view along b-b in FIG. 2 and is a cross-sectional view in the longitudinal direction of the raised electrode 123. Further, FIG. 5 is a cross-sectional view along c-c in FIG. 2 and is a cross-sectional view in the short-side direction of the first raised electrode 112. As illustrated in FIG. 4, the lower electrode 22 is formed on the insulating film 31. The lower electrode 22 passes through the gate trench 111 and is extended to the raised electrode 123. Further, the lower electrode 22 is raised to the surface of the semiconductor substrate at the raised electrode 123. Specifically, as illustrated in FIG. 5, the lower electrode 22 is raised to the surface of the p⁺-type layer region 23. The interlayer insulating film 30 is formed on the lower electrode 22 that is raised. The lower electrode 22 is connected to the emitter electrode 51 via the contact via 42 at the first raised electrode 112. The contact via 42 penetrates the interlayer insulating film 30.

As described above, according to the present disclosure, the lower electrode 22 is connected to the contact via 42 at the first raised electrode 112 having a wider width. Further, by the second raised electrode 113 having a narrower width being positioned between the first raised electrode 112 and the gate trench 111, an embedding defect of the lower electrode 22 at ends of the raised electrode 123 is avoided. This makes it possible to provide a semiconductor device capable of preventing a short-circuit of the upper electrode 21 and the lower electrode 22 while securing a bonding margin between the lower electrode 22 and the contact via 42.

Note that effects similar to the effects of the first embodiment can be obtained also in the following modifications.

### First Modification of First Embodiment

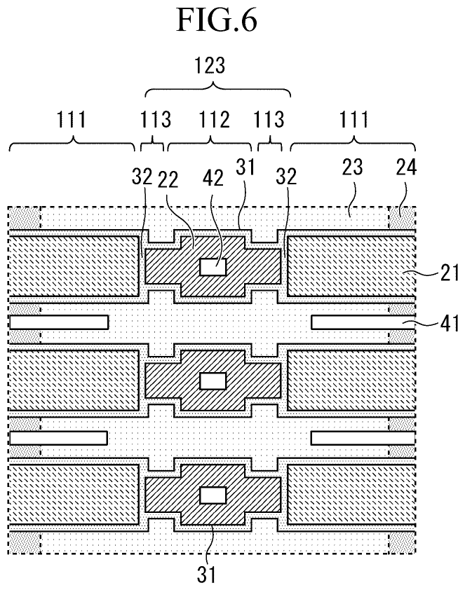

FIG. 6 is a plan view of the semiconductor device 101 according to a modification of the first embodiment of the present disclosure. Here, the gate trench 111 has the width equal to the width of the first raised electrode 112. In this manner, the gate trench 111 may have a wide width.

### Second Modification of First Embodiment

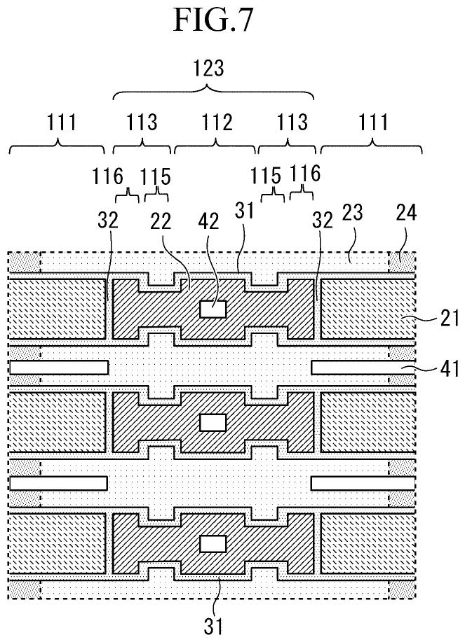

FIG. 7 is a plan view of the semiconductor device 101 according to a modification of the first embodiment of the present disclosure. Here, the second raised electrode 113 includes a narrow width portion 115 connected to the first raised electrode 112 and a wide width portion 116 that is connected to the gate trench 111 via the intermediate insulating film 32 and that has a wider width than the width of the narrow width portion 115. While the wide width portion 116 preferably has the width equal to the width of the first raised electrode 112, the wide width portion 116 only requires to have a width wider than the width of the narrow width portion 115.

### Third Modification of First Embodiment

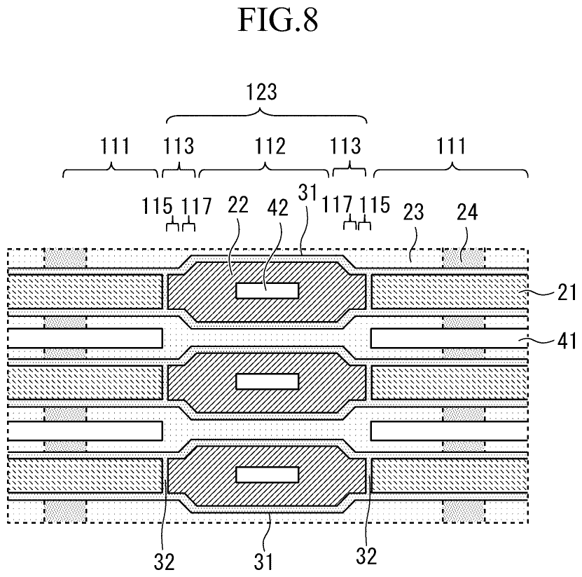

FIG. 8 is a plan view of the semiconductor device 101 according to a modification of the first embodiment of the present disclosure. Here, the second raised electrode 113 includes the narrow width portion 115, having a narrower width than the width of the first raised electrode 112, and a connection portion 117 that connects the narrow width portion 115 and the first raised electrode 112 in an inclined manner in plan view. The narrow width portion 115 is connected to the gate trench 111 via the intermediate insulating film 32. By connecting the portions having different widths in an inclined manner, it is possible to alleviate electric field concentration at a corner portion of the raised electrode 123. While a case has been described in the example in FIG. 8 where the connection portion 117 connects the narrow width portion 115 and the first raised electrode 112 in an inclined manner, similar effects can be obtained even if the connection portion 117 connects the narrow width portion 115 and the first raised electrode 112 in a curved manner. Note that this point is common among all the following embodiments.

Note that the semiconductor substrate 10 is not limited to one formed of silicon and may be formed of a wide bandgap semiconductor having a larger bandgap than the bandgap of silicon. The wide bandgap semiconductor is, for example, silicon carbide, a gallium nitride material or diamond. The semiconductor substrate 10 formed of such a wide bandgap semiconductor has a high withstand voltage and high allowable current density, so that it is possible to make the semiconductor device 101 smaller. Use of such a semiconductor device 101 made smaller can also make a semiconductor module incorporating this semiconductor device 101 smaller and higher integrated. Further, the semiconductor device 101 has high heat resistance, and thus, a radiating fin of a heatsink can be made smaller, and a water-cooling unit can be air-cooled, so that it is possible to make the semiconductor module further smaller. Further, the semiconductor device 101 has low power loss and operates with high efficiency, and thus, the semiconductor module can be made to operate with higher efficiency. Note that this point is common among all the following embodiments.

### Second Embodiment

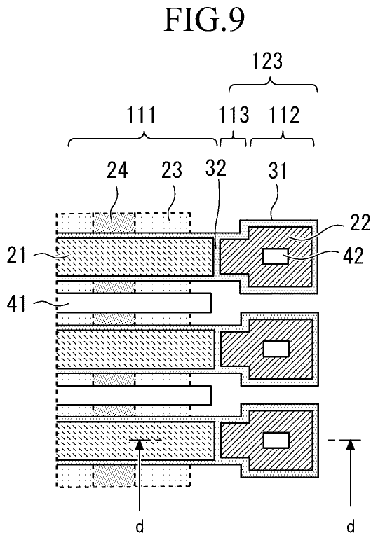

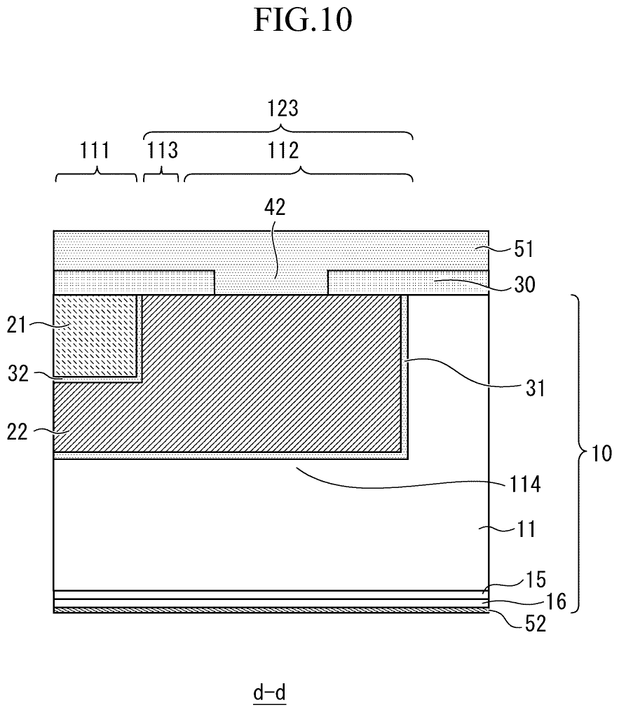

Hereafter, changes from the first embodiment will be described. FIG. 9 is a plan view of the semiconductor device 101 according to a second embodiment of the present disclosure. Further, FIG. 10 is a cross-sectional view along d-d in FIG. 9. In the present embodiment, the raised electrode 123 is formed at a terminal portion 103 of the gate trench 111. This can make the configuration of the gate trench 111 in the active region 102 uniform, so that it is possible to obtain an effect of making heat generation of the semiconductor device 101 uniform in a plane of the active region 102 in addition to the effects described in the first embodiment.

Note that effects similar to the effects of the second embodiment can be obtained also in the following modifications.

### First Modification of Second Embodiment

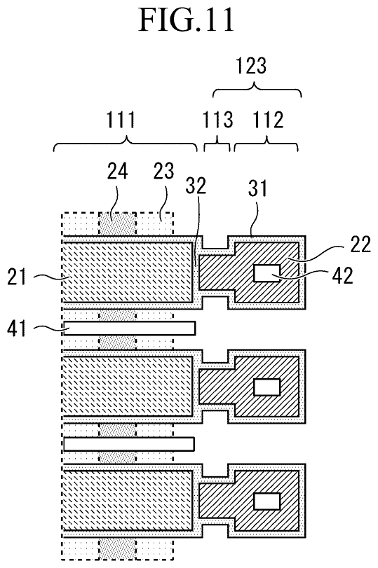

FIG. 11 is a plan view of the semiconductor device 101 according to a modification of the second embodiment of the present disclosure. Here, the gate trench 111 has the width equal to the width of the first raised electrode 112. In this manner, the gate trench 111 may have a wide width.

### Second Modification of Second Embodiment

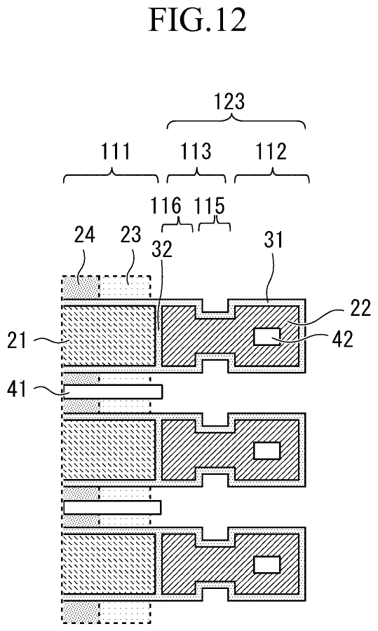

FIG. 12 is a plan view of the semiconductor device 101 according to a modification of the second embodiment of the present disclosure. Here, the second raised electrode 113 includes the narrow width portion 115 connected to the first raised electrode 112 and the wide width portion 116 that is connected to the gate trench 111 via the intermediate insulating film 32 and that has a wider width than the width of the narrow width portion 115. While the wide width portion 116 preferably has the width equal to the width of the first raised electrode 112, the wide width portion 116 only requires to have a width wider than the width of the narrow width portion 115.

### Third Embodiment

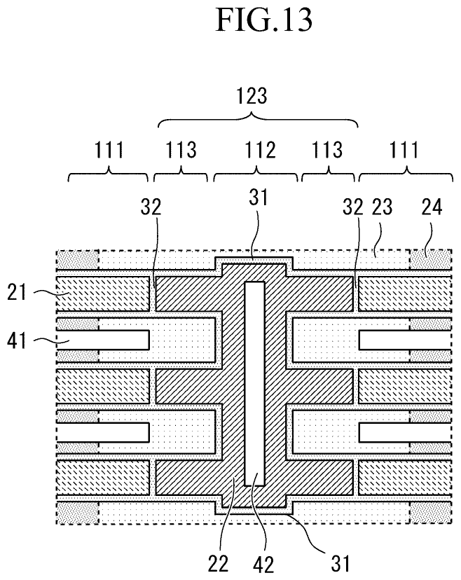

Hereafter, changes from the first embodiment will be described. FIG. 13 is a plan view of the semiconductor device 101 according to a third embodiment of the present disclosure. While an example is illustrated here where the second raised electrode 113 has the width equal to the width of the gate trench 111, the second raised electrode 113 may have a width different from the width of the gate trench 111.

In the present embodiment, a plurality of gate trenches 111 are connected to the first raised electrode 112 via the second raised electrode 113. The lower electrode 22 is connected to the contact via 42 at the first raised electrode 112.

This can make the area of the first raised electrode 112 larger than that in the first embodiment. It is therefore possible to further increase the bonding margin between the lower electrode 22 and the contact via 42.

Further, the area of the contact via 42 can be increased by an amount corresponding to an increase in the width of the lower electrode 22, so that it is possible to lower contact resistance compared to the first embodiment.

### First Modification of Third Embodiment

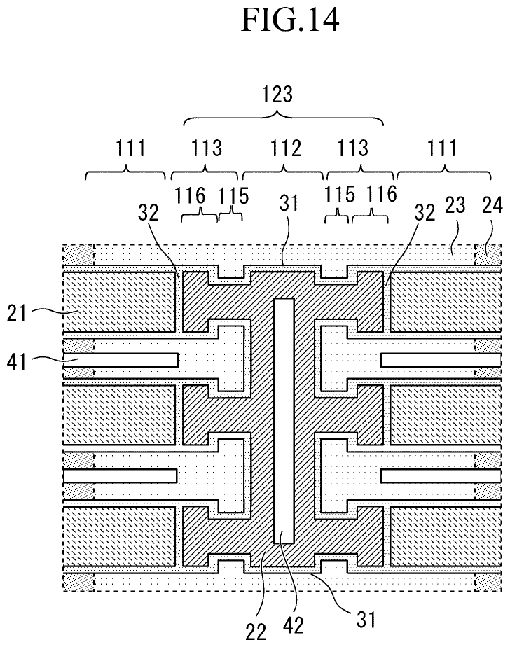

FIG. 14 is a plan view of the semiconductor device 101 according to a modification of the third embodiment of the present disclosure. Here, the second raised electrode 113 includes the narrow width portion 115 connected to the first raised electrode 112 and the wide width portion 116 that is connected to the gate trench 111 via the intermediate insulating film 32 and that has a width wider than the width of the narrow width portion 115. The wide width portion 116 only requires to have a width wider than the width of the narrow width portion 115. Effects similar to the effects of the third embodiment can be obtained also in such a modification.

### Fourth Embodiment

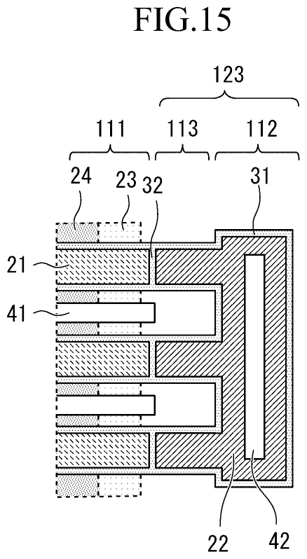

Hereafter, changes from the third embodiment will be described. FIG. 15 is a plan view of the semiconductor device 101 according to a fourth embodiment of the present disclosure. In the present embodiment, the raised electrode 123 of the third embodiment is formed at the terminal portion 103 of the gate trench 111.

By this means, combined effects of the second embodiment and the third embodiment can be obtained.

### First Modification of Fourth Embodiment

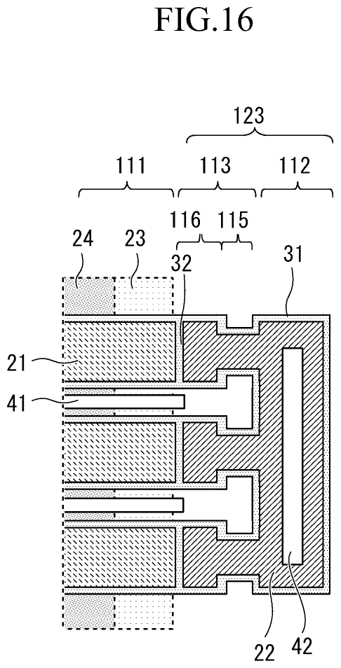

FIG. 16 is a plan view of the semiconductor device 101 according to a modification of the fourth embodiment of the present disclosure. Here, the second raised electrode 113 includes the narrow width portion 115 connected to the first raised electrode 112 and the wide width portion 116 that is connected to the gate trench 111 via the intermediate insulating film 32 and that has a width wider than the width of the narrow width portion 115. The wide width portion 116 only requires to have a width wider than the width of the narrow width portion 115. Effects similar to the effects of the fourth embodiment can be obtained also in such a modification.

### Fifth Embodiment

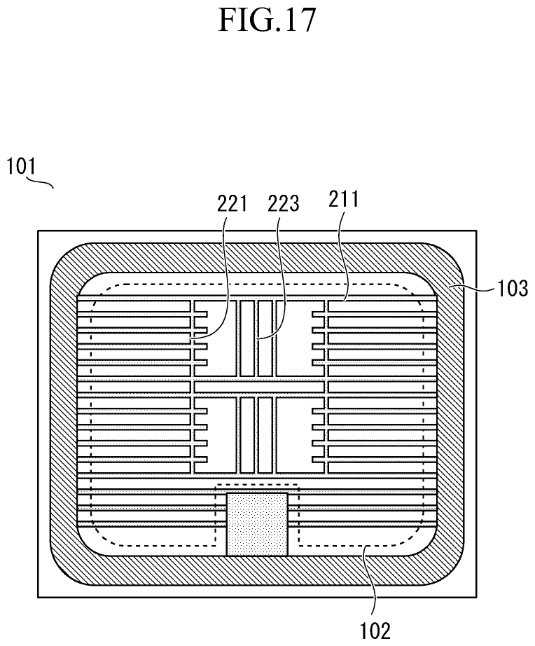

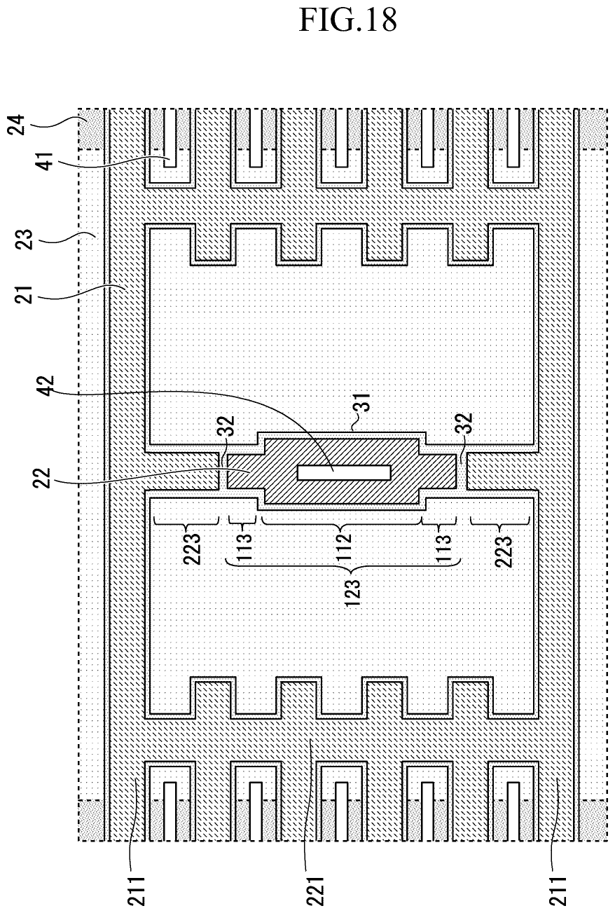

Hereafter, changes from the first embodiment will be described. FIG. 17 is a plan view of the semiconductor device 101 according to a fifth embodiment of the present disclosure. Further, FIG. 18 is an enlarged view of FIG. 17. The gate trench 111 of the present embodiment includes a plurality of parallel gate trenches 211 arranged in parallel in plan view. The plurality of parallel gate trenches 211 is connected by the gate trench 221 that extends in a direction perpendicular to the extending direction of the parallel gate trenches 211. This can collectively set the lower electrodes 22 of the parallel gate trenches 211 connected by the gate trench 221 at the emitter potential.

Further, two out of the plurality of parallel gate trenches 211 are connected to the raised electrode 123 formed between the two parallel gate trenches 211 via the gate trench 223. This makes it possible to provide a large first raised electrode 112 utilizing a space between the two parallel gate trenches 211, so that it is possible to increase a bonding margin between the lower electrode 22 and the contact via 42. Further, it is possible to more freely adjust layout of the raised electrode 123. In the example in FIG. 17, the parallel gate trenches 211 at both ends, among the plurality of parallel gate trenches 211 connected by the gate trench 221, are connected to the raised electrode 123 via the gate trench 223. By connecting the parallel gate trenches 211 at both ends, it is possible to provide a large first raised electrode 112.

### First Modification of Fifth Embodiment

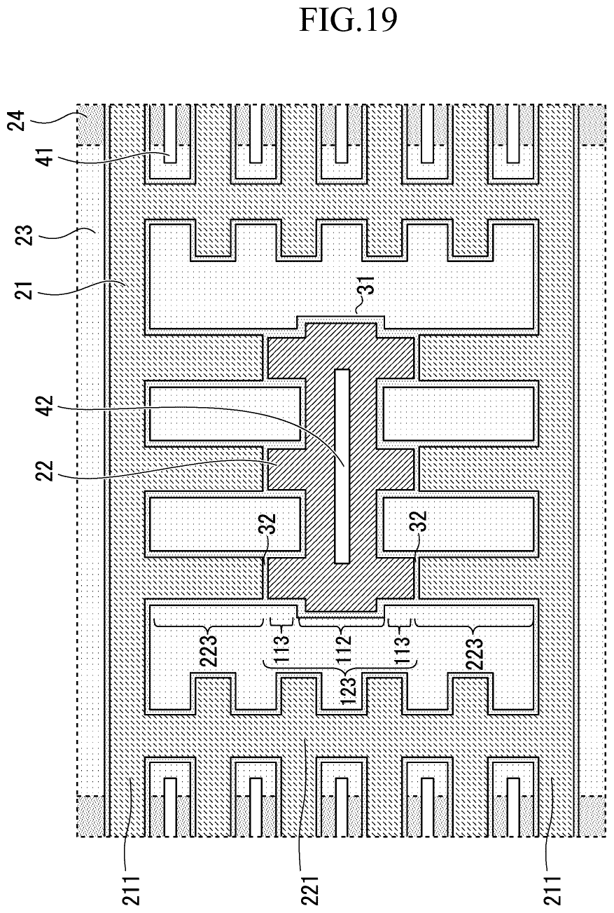

FIG. 19 is a plan view of the semiconductor device 101 according to a modification of the fifth embodiment of the present disclosure. Here, a plurality of gate trenches 223 that are parallel to each other in plan view are connected to the raised electrode 123. Effects similar to the effects of the fifth embodiment can be obtained also in such a modification.

Note that the present disclosure is not limited to the above-described embodiments and can be modified in various ways within a range not deviating from the gist in an implementation stage. Further, the respective embodiments can be combined as appropriate, in which case the combined effects can be obtained.

### CORRESPONDENCE WITH TERMS USED IN CLAIMS

The n-type semiconductor conductivity type will be referred to as a first conductivity type in the claims. In a similar manner, the p-type semiconductor conductivity type will be referred to as a second conductivity type in the claims. In association with this, in the claims, the n-type drift layer 11, the p-type base layer 13, and the n⁺-type emitter region 24 will be respectively referred to as a drift layer of a first conductivity type, a base layer of a second conductivity type, and an emitter region of the first conductivity type.

Hereinafter, various aspects of the present disclosure will be collectively described as appendixes.

### Appendix 1

A semiconductor device comprising:
a semiconductor substrate including a drift layer of a first conductivity type, a base layer of a second conductivity type formed on the drift layer, and an emitter region of the first conductivity type formed in an upper layer portion of the base layer;
a gate insulating film formed on an inner wall of a groove that penetrates the emitter region and the base layer from a surface of the semiconductor substrate to reach the drift layer;
a gate trench and a raised electrode that are formed inside the groove on the gate insulating film;
an interlayer insulating film formed on the gate trench and the raised electrode; and
an emitter electrode formed on the semiconductor substrate and the interlayer insulating film and connected to the emitter region and the base layer,
wherein the gate trench includes a lower electrode formed inside the groove and an upper electrode formed inside the groove above the lower electrode via an intermediate insulating film,
the raised electrode connects the lower electrode to the emitter electrode and is insulated from the upper electrode by the intermediate insulating film,
the raised electrode includes a first raised electrode and a second raised electrode, the first raised electrode being connected to the emitter electrode via a contact via that penetrates the interlayer insulating film, the second raised electrode being positioned between the first raised electrode and the gate trench in a direction in which the groove extends in plan view, and
the second raised electrode includes a narrow width portion having a width narrower than a width of the first raised electrode in plan view.

### Appendix 2

The semiconductor device according to appendix 1,
wherein the semiconductor device includes a plurality of the gate trenches, and
the gate trenches are connected to the first raised electrode via the second raised electrode.

### Appendix 3

The semiconductor device according to appendix 1 or 2, wherein the raised electrode is formed at a terminal portion of the groove.

### Appendix 4

The semiconductor device according to any one of appendixes 1 through 3, wherein the second raised electrode includes the narrow width portion and a wide width portion having a width wider than the width of the narrow width portion in plan view, the narrow width portion being connected to the first raised electrode, the wide width portion being connected to the gate trench via the intermediate insulating film.

### Appendix 5

The semiconductor device according to any one of appendixes 1 through 3, wherein the second raised electrode includes the narrow width portion and a connection portion that connects the narrow width portion and the first raised electrode in an inclined manner or in a curved manner in plan view.

### Appendix 6

The semiconductor device according to appendix 1 or 3, wherein the gate trench has a width equal to the width of the first raised electrode or the width of the narrow width portion of the second raised electrode in plan view.

### Appendix 7

The semiconductor device according to appendix 1,
wherein the gate trench includes two parallel gate trenches arranged in parallel in plan view, and
the parallel gate trenches are connected to the raised electrode formed between the parallel gate trenches via the gate trench.

### Appendix 8

The semiconductor device according to appendix 7, wherein a plurality of the gate trenches that are parallel to each other in plan view are connected to the raised electrode.

### Appendix 9

The semiconductor device according to any one of appendixes 1 through 8, wherein the semiconductor substrate is formed of a wide bandgap semiconductor.

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2023-196912, filed on Nov. 20, 2023 including specification, claims, drawings and summary, on which the convention priority of the present application is based, is incorporated herein by reference in its entirety.

1. A semiconductor device comprising:
a semiconductor substrate including a drift layer of a first conductivity type, a base layer of a second conductivity type formed on the drift layer, and an emitter region of the first conductivity type formed in an upper layer portion of the base layer;
a gate insulating film formed on an inner wall of a groove that penetrates the emitter region and the base layer from a surface of the semiconductor substrate to reach the drift layer;
a gate trench and a raised electrode that are formed inside the groove on the gate insulating film;
an interlayer insulating film formed on the gate trench and the raised electrode; and
an emitter electrode formed on the semiconductor substrate and the interlayer insulating film and connected to the emitter region and the base layer,
wherein the gate trench includes a lower electrode formed inside the groove and an upper electrode formed inside the groove above the lower electrode via an intermediate insulating film,
the raised electrode connects the lower electrode to the emitter electrode and is insulated from the upper electrode by the intermediate insulating film,
the raised electrode includes a first raised electrode and a second raised electrode, the first raised electrode being connected to the emitter electrode via a contact via that penetrates the interlayer insulating film, the second raised electrode being positioned between the first raised electrode and the gate trench in a direction in which the groove extends in plan view, and
the second raised electrode includes a narrow width portion having a width narrower than a width of the first raised electrode in plan view.

2. The semiconductor device according to claim 1,
wherein the semiconductor device includes a plurality of the gate trenches, and
the gate trenches are connected to the first raised electrode via the second raised electrode.

3. The semiconductor device according to claim 1, wherein the raised electrode is formed at a terminal portion of the groove.

4. The semiconductor device according to claim 2, wherein the raised electrode is formed at a terminal portion of the groove.

5. The semiconductor device according to claim 1, wherein the second raised electrode includes the narrow width portion and a wide width portion having a width wider than the width of the narrow width portion in plan view, the narrow width portion being connected to the first raised electrode, the wide width portion being connected to the gate trench via the intermediate insulating film.

6. The semiconductor device according to claim 2, wherein the second raised electrode includes the narrow width portion and a wide width portion having a width wider than the width of the narrow width portion in plan view, the narrow width portion being connected to the first raised electrode, the wide width portion being connected to the gate trench via the intermediate insulating film.

7. The semiconductor device according to claim 1, wherein the second raised electrode includes the narrow width portion and a connection portion that connects the narrow width portion and the first raised electrode in an inclined manner or in a curved manner in plan view.

8. The semiconductor device according to claim 2, wherein the second raised electrode includes the narrow width portion and a connection portion that connects the narrow width portion and the first raised electrode in an inclined manner or in a curved manner in plan view.

9. The semiconductor device according to claim 1, wherein the gate trench has a width equal to the width of the first raised electrode or the width of the narrow width portion of the second raised electrode in plan view.

10. The semiconductor device according to claim 1,
wherein the gate trench includes two parallel gate trenches arranged in parallel in plan view, and
the parallel gate trenches are connected to the raised electrode formed between the parallel gate trenches via the gate trench.

11. The semiconductor device according to claim 10, wherein a plurality of the gate trenches that are parallel to each other in plan view are connected to the raised electrode.

12. The semiconductor device according to claim 1, wherein the semiconductor substrate is formed of a wide bandgap semiconductor.

13. The semiconductor device according to claim 2, wherein the semiconductor substrate is formed of a wide bandgap semiconductor.
